(19) United States
(12) Patent Application Publication
(10) Pub. No.: US 2016/0237569 A1
(43) Pub. Date: Aug. 18, 2016

(54) SEMICONDUCTOR MANUFACTURING APPARATUS

(71) Applicant: KABUSHIKI KAISHA TOSHIBA, Minato-ku (JP)

(72) Inventors: Hideaki MASUDA, Nagoya (JP); Katsuyasu SHIBA, Yokkaichi (JP)

(73) Assignee: KABUSHIKI KAISHA TOSHIBA, Minato-ku (JP)

(21) Appl. No.: 14/847,735

(22) Filed: Sep. 8, 2015

Related U.S. Application Data
(60) Provisional application No. 62/115,331, filed on Feb. 12, 2015.

(51) Int. Cl. C23C 16/46; H01J 37/32; C23C 16/50; C23C 16/458

(52) U.S. Cl. CPC C23C 16/46; C23C 16/458; H01J 37/32009; C23C 16/50; H01J 2237/334; H01J 2237/3321

(57) ABSTRACT

A semiconductor manufacturing apparatus according to an embodiment includes a heater, a sidewall, and a moving mechanism. The heater is capable of heating a semiconductor substrate. The sidewall is located at an outer edge of the heater and protrudes upward from a mount face of the heater on which the semiconductor substrate is mounted. The moving mechanism relatively moves at least a part of the sidewall and the heater in a substantially perpendicular direction with respect to the mount face.

### CROSS REFERENCE TO RELATED APPLICATIONS

This application is based upon and claims the benefit of priority from the prior U.S. Provisional Patent Application No. 62/115,331 filed on Feb. 12, 2015, the entire contents of which are incorporated herein by reference.

### FIELD

Embodiments relate to a semiconductor manufacturing apparatus.

### BACKGROUND

A CVD (Chemical Vapor Deposition) apparatus is conventionally used in a semiconductor manufacturing process. A heater that heats a wafer is provided in a chamber of the CVD apparatus, for example, to control a deposition rate in a film formation process. The heater has a pocket (that is, a counterbore part) surrounded by a sidewall to mount the wafer thereon. The wafer transported to the CVD apparatus is supported above the heater by lift pins and then the lift pins are lowered to mount the wafer on a mount face, which is the bottom face of the pocket.

However, the wafer may be deviated from the mount face due to deviation in support positions of the wafer by the lift pins, or the like. If the wafer is deviated from the mount face, the wafer may run the sidewall over, which causes a gap between the wafer and the mount face. In this case, the temperature of the wafer is locally lowered due to the gap and thus the film thickness in the plane of the wafer becomes non-uniform. For example, in a process that is sensitive to the temperature of a wafer such as a non-doped silicate glass (NSG) film, the deposition rate is increased in a portion where the temperature is locally lowered as compared to other portions, which locally increases the film thickness.

Therefore, to improve the uniformity in the film thickness, it is required to eliminate positional deviation of the wafer with respect to the mount face to enable a gap between the wafer and the mount face to be eliminated.

### BRIEF DESCRIPTION OF THE DRAWINGS

FIG. 1 is a schematic cross-sectional view of a semiconductor manufacturing apparatus 1 according to a first embodiment;

FIG. 2 is a plan view of a heater 12 of the semiconductor manufacturing apparatus 1 shown in FIG. 1;

FIG. 3A shows a semiconductor substrate 2 supported by lift pins 16 of the semiconductor manufacturing apparatus 1 shown in FIG. 1, FIG. 3B shows the semiconductor substrate 2 having positional deviation, and FIG. 3C shows the semiconductor substrate 2 from which the positional deviation has been eliminated;

FIG. 4 is a plan view of the heater 12, showing a modification of the first embodiment;

FIG. 5 shows the semiconductor manufacturing apparatus 1 according to a second embodiment; and

FIG. 6 shows the semiconductor substrate 2 from which positional deviation has been eliminated in the semiconductor manufacturing apparatus 1 shown in FIG. 5.

### DETAILED DESCRIPTION

According to an embodiment, a semiconductor manufacturing apparatus includes a heater, a sidewall, and a moving mechanism. The heater is capable of heating a semiconductor substrate. The sidewall is located at an outer edge of the heater and protrudes upward from a mount face of the heater on which the semiconductor substrate is mounted. The moving mechanism relatively moves at least a part of the sidewall and the heater in a substantially perpendicular direction with respect to the mount face.

Embodiments will now be explained with reference to the accompanying drawings. The present invention is not limited to the embodiments.

### First Embodiment

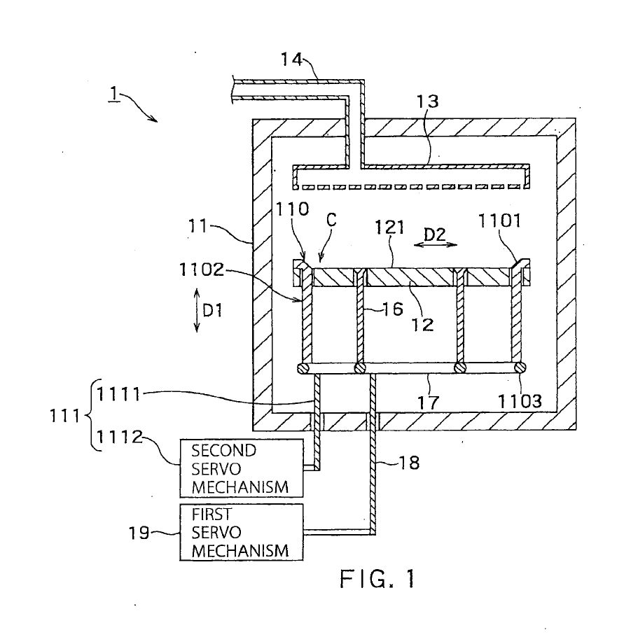

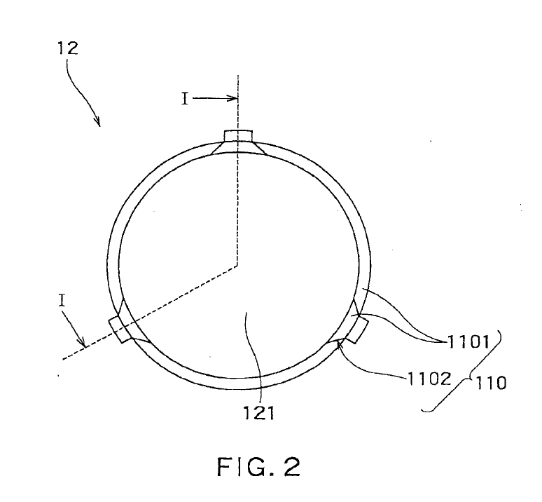

First, an embodiment of a semiconductor manufacturing apparatus in which a part of a sidewall is a moving part is explained as a first embodiment. FIG. 1 is a schematic cross-sectional view of a semiconductor manufacturing apparatus 1 according to the first embodiment. FIG. 2 is a plan view of a heater 12 of the semiconductor manufacturing apparatus 1 shown in FIG. 1. FIG. 1 is also a cross-sectional view along a line I-I in FIG. 2.

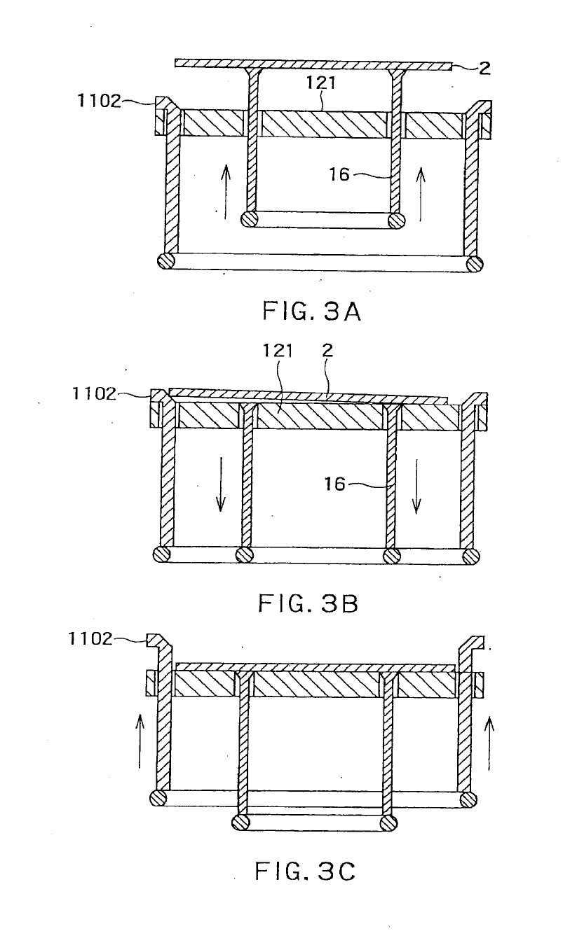

The semiconductor manufacturing apparatus 1 shown in FIG. 1 is a plasma CVD apparatus that performs a film formation process through plasma CVD. The semiconductor manufacturing apparatus 1 includes a susceptor 12 and a showerhead electrode 13 that face each other in a vertical direction D1 inside a chamber 11. A semiconductor substrate 2 (a wafer) (see FIG. 3) can be mounted on the susceptor 12. The susceptor 12 functions as an electrode that produces plasma and functions also as a heater (explained later). The showerhead electrode 13 is a hollow electrode having nozzles. A source gas is supplied into the showerhead electrode 13 from a supply source (not shown) of the source gas via a pipe 14. The showerhead electrode 13 discharges the supplied source gas toward the semiconductor substrate 2 through the nozzles. A high-frequency wave is applied by a power supply (not show) to the showerhead electrode 13 or the susceptor 12. The source gas discharged into the chamber 11 in a vacuum state is ionized by an electric field based on the high-frequency wave, thereby becoming deposition species.

The deposition species move onto the semiconductor substrate 2, thereby forming a film.

The susceptor 12 has a function of a heater capable of heating the semiconductor substrate 2. The susceptor 12 is hereinafter referred to also as “heater 12”. The heater 12 can, for example, incorporate therein a heating wire that generates heat due to application of current and heat the semiconductor substrate 2 using generated heat of the heating wire. With the heater 12, the deposition rate (that is, the film formation rate) can be adjusted by heating the semiconductor substrate 2.

The heater 12 has a mount face 121 on which the semiconductor substrate 2 is mounted. The mount face 121 is, for example, a circular area on a surface of the heater 12.

The semiconductor manufacturing apparatus 1 also includes a plurality of lift pins 16 that mounts the semiconductor substrate 2 on the mount face 121. The lift pins 16 extend in the vertical direction D1 to pass through the heater 12. The lift pins 16 can be moved (raised) to a substrate reception position (explained later) to support the semiconductor substrate 2 transported into the chamber 11. The lift pins 16 can be moved (lowered) to a substrate mount position (explained later) while supporting the semiconductor substrate 2, thereby mounting the semiconductor substrate 2 on the mount face 121.

Respective lower ends of the lift pins 16 are coupled together by an annular first coupling ring 17. The first coupling ring 17 is fixed to a first drive rod 18 that raises or lowers the lift pins 16 together. The first drive rod 18 extends downward to pass through the chamber 11 and is connected at a lower end to a first servo mechanism 19 outside the chamber 11. The first servo mechanism 19 can, for example, include a motor, a gear that converts a rotational motion of the motor to a translational motion in the vertical direction D1 and that transmits the translational motion to the first drive rod 18, and a controller for the motor.

The semiconductor manufacturing apparatus 1 also includes a sidewall 110 provided at an outer edge of the heater 12. As shown in FIG. 2, the sidewall 110 is annular and surrounds the entire periphery of the mount face 121. As shown in FIG. 1, the sidewall 110 protrudes upward from the mount face 121. A portion 1101 of a top face of the sidewall 110 in a predetermined range on an inner side (the side of the center of the heater 12) is inclined downward as approaching the heater 12. The inclined portion 1101 of the top face of the sidewall 110 is hereinafter referred to also as “inclined face 1101”.

The sidewall 110 forms a counterbore part C together with the mount face 121. Specifically, the mount face 121 forms the bottom face of the counterbore part C and the top face (the inclined face 1101) of the sidewall 110 forms the side face of the counterbore part C. The inclination angle of the inclined face 1101 is substantially uniform (including uniform) all around the sidewall 110. Although not limited thereto, the inclination angle of the inclined face 110 can be, for example, 45 degrees with respect to the mount face 121.

If the semiconductor substrate 2 is deviated from the mount face 121, the semiconductor substrate 2 becomes a state partially running the sidewall 110 over, that is, a state inclined with respect to the mount face 121. In this case, because the inclined face 1101 is provided on the sidewall 110, the semiconductor substrate 2 slides in a radial direction D2 along the inclined face 1101 under its own weight. Due to being capable of sliding, the semiconductor substrate 2 can modify the mount position to bring the entire rear surface into contact with the mount face 121. That is, positional deviation of the semiconductor substrate 2 from the mount face 121 can be eliminated. The sidewall 110 has an annular shape and thus, in whichever radial direction D2 the semiconductor substrate 2 is deviated from the mount face 121, the semiconductor substrate 2 can be in contact with the inclined face 1101 in the direction of deviation. Accordingly, in whichever direction the semiconductor substrate 2 is deviated, the positional deviation of the semiconductor substrate 2 can be eliminated using the inclination of the inclined face 1101. When the semiconductor substrate 2 is thus moved along the inclined face 1101 to an appropriate position under its own weight, no problems occur. However, if the semiconductor substrate 2 runs the sidewall 110 over and then stops, process variation occurs in the plane of the semiconductor substrate 2 as described above.

For example, when the positional deviation of the semiconductor substrate 2 is small, the positional deviation can be eliminated by using the inclination of the inclined face 1101 in the manner as described above. However, if the positional deviation of the semiconductor substrate 2 is large, it is difficult to reliably eliminate the positional deviation only by using the inclination of the inclined face 1101. When the positional deviation is large, the semiconductor substrate 2 stops due to frictional force or the like before reaching the bottom of the inclined face 1101 even if the semiconductor substrate 2 can slide on the inclined face 1101. In this case, the semiconductor substrate 2 is kept running the sidewall 110 over and the positional deviation cannot be eliminated.

To address this problem, the semiconductor manufacturing apparatus 1 includes a moving part 1102 and a moving mechanism 111 to reliably eliminate positional deviation of the semiconductor substrate 2 from the mount face 121.

As shown in FIG. 2, the moving part 1102 is a part of the sidewall 110 and a plurality (three, for example) of the moving parts 1102 are provided along the outer edge of the mount face 121 at substantially equal intervals (including equal intervals).

The moving parts 1102 are movable in a substantially perpendicular direction (including a perpendicular direction) with respect to the mount face 121. The moving parts (movable parts) 1102 can have an arbitrary shape as long as it has the inclined face 1101 and a claw shape, a pin shape, a rod shape, or the like can be used.

As shown in FIG. 1, the moving parts 1102 pass through the heater 12 to extend to below the heater 12. An annular second coupling ring 1103 that couples the moving parts 1102 together is fixed to respective lower ends of the moving parts 1102.

The moving mechanism 111 relatively moves at least a part of the sidewall 110 and the heater 12 in a direction substantially perpendicular to the mount face 121. Specifically, the moving mechanism 111 moves the moving parts 1102 in the vertical direction D1. More specifically, the moving mechanism 111 includes a second drive rod 1111 that drives the moving parts 1102, and a second servo mechanism 1112 serving as a power source of the second drive rod 1111. The second drive rod 1111 extends in the vertical direction D1 and is fixed at an upper end to the second coupling ring 1103. A portion of the second drive rod 1111 on the side of a lower end passes through the chamber 11 to be drawn outside. The lower end of the second drive rod 1111 is connected to the second servo mechanism 1112 outside the chamber 11.

The second servo mechanism 1112 transmits power in the vertical direction D1 to the second drive rod 1111. The second servo mechanism 1112 can include, for example, a motor, a gear that converts a rotational motion of the motor to a translational motion in the vertical direction D1 and that transmits the translational motion to the second drive rod 1111, and a controller for the motor.

With the moving parts 1102 and the moving mechanism 111, the inclined faces 1101 of the moving parts 1102 can be raised with respect to the mount face 121. With rise of the inclined faces 1101 of the moving parts 1102, the angles (the inclinations) of the semiconductor substrate 2 with respect to the inclined faces 1101 and the mount face 121 change and thus a balance of force (frictional force or moment) that is stopping (immobilizing) the semiconductor substrate 2 is lost between the semiconductor substrate 2, and the inclined faces 1101 and the mount face 121. This enables the semiconductor substrate 2 to slide on the inclined faces 1101 under its own weight and thus the positional deviation of the semiconductor substrate 2 can be reliably eliminated.

An operation example of the semiconductor manufacturing apparatus 1 shown in FIG. 1 is explained next with reference to FIGS. 3. FIG. 3A shows the semiconductor substrate 2 supported by the lift pins 16 of the semiconductor manufacturing apparatus 1 shown in FIG. 1. FIG. 3B shows the semiconductor substrate 2 having positional deviation. FIG. 3C shows the semiconductor substrate 2 from which the positional deviation has been eliminated. In FIGS. 3A and 3B, arrows indicate a moving direction of the lift pins 16. In FIG. 3C, arrows indicate a moving direction of the moving parts 1102.

First, the lift pins 16 are raised by power of the first servo mechanism 19 (see FIG. 1) from a reference position to a substrate reception position where the semiconductor substrate 2 is received. FIG. 3A shows the lift pins 16 raised to the substrate reception position. The reference position can be a position where upper ends of the lift pins 16 are on the same level as the mount face 121 (see FIG. 1). In this case, the reference position matches a substrate mount position where the semiconductor substrate 2 is mounted on the mount face 121.

At the substrate reception position, the semiconductor substrate 2 is transported by a transport robot (not shown) to the upper ends of the lift pins 16. The lift pins 16 then receive the transported semiconductor substrate 2. Specifically, as shown in FIG. 3A, the lift pins 16 support the rear surface of the transported semiconductor substrate 2 from below. The moving parts 1102 are at a position (a reference position) on the same level as other portions of the sidewall 110 until the lift pins 16 are moved to the substrate mount position.

Next, the lift pins 16 are lowered by power of the first servo mechanism 19 to the substrate mount position while supporting the semiconductor substrate 2. Subsequently, as shown in FIG. 3B, the lift pins 16 mounts the semiconductor substrate 2 on the mount face 121 at the substrate mount position. At that time, the semiconductor substrate 2 may run the sidewall 110 over due to deviation of the semiconductor substrate 2 from the mount face 121. In a case where the positional deviation of the semiconductor substrate 2 is large, even if the semiconductor substrate 2 can slide along the inclined face 1101, the slide of the semiconductor substrate 2 is restricted by frictional force with the inclined faces 1101 or the mount face 121 and consequently the semiconductor substrate 2 stops while running the inclined face 1101 over.

Next, the moving parts 1102 are raised by the moving mechanism 111. With rise of the moving parts 1102, a balance of force (the frictional force or moment) that is stopping the semiconductor substrate 2 is lost and thus the semiconductor substrate 2 becomes capable of sliding easily along the inclined faces 1101 of the moving parts 1102 under its own weight. Accordingly, the mount position of the semiconductor substrate 2 is modified from a position where the semiconductor substrate 2 is running the sidewall 110 over to a position where the semiconductor substrate 2 falls into place on the mount face 121, thereby eliminating the positional deviation.

Subsequently, the moving parts 1102 are lowered by the moving mechanism 111 from the most raised position to a position on the same level as other portions of the sidewall 110.

Thereafter, the source gas is supplied into the chamber 11 and plasma is produced between the susceptor 12 as the electrode and the electrode 13, thereby forming a film on the semiconductor substrate 2. During formation of a film, the semiconductor substrate 2 is heated by the heater 12 to control the deposition rate of the film. At that time, because the positional deviation of the semiconductor substrate 2 is eliminated, there is no gap between the semiconductor substrate 2 and the mount face 121. Therefore, a local temperature decrease in the semiconductor substrate 2 due to a gap can be avoided and the deposition rate in the plane of the semiconductor substrate 2 can be uniformized. Uniformization of the deposition rate can enhance the uniformity in the film thickness in the plane of the semiconductor substrate 2.

As described above, with the semiconductor manufacturing apparatus 1 according to the first embodiment, the moving parts 1102 can be raised with respect to the mount face 121 and thus positional deviation of the semiconductor substrate 2 can be reliably eliminated. As a result, the uniformity in the film thickness can be enhanced.

The first embodiment is also applicable to formation of a non-doped silicate glass film on the semiconductor substrate 2. A film formation process of a non-doped silicate glass film is a process sensitive to the temperature and the film thickness is likely to become non-uniform due to a local temperature decrease in the semiconductor substrate 2 based on a gap between the mount face 121 and the semiconductor substrate 2. Because positional deviation of the semiconductor substrate 2 can be eliminated according to the first embodiment, the gap between the semiconductor substrate 2 and the mount face 121 can be reliably eliminated. Because the gap can be eliminated, respective portions of the semiconductor substrate 2 can be heated uniformly and a local temperature decrease can be avoided. As a result, a non-doped silicate glass film with a uniform thickness can be formed. The first embodiment is applicable to a formation process of films other than the non-doped silicate glass film.

The first embodiment is also applicable to a film formation process using thermal CVD. When the first embodiment is applied to the thermal CVD, it suffices to provide a stage having a heater incorporated therein instead of the susceptor 12. The first embodiment is also applicable to reactive ion etching (RIE).

### (Modification)

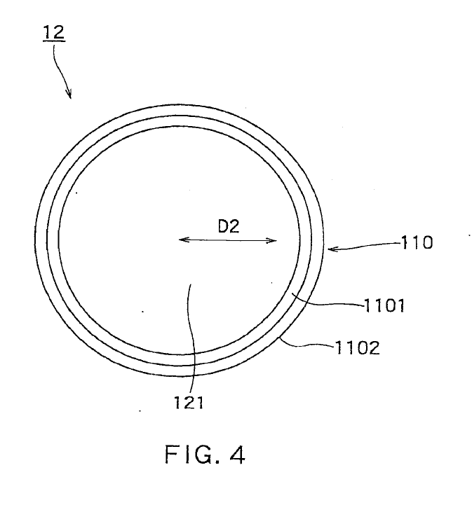

A modification of the first embodiment in which the entire sidewall is a moving part is explained next. In the explanations of the present modification, as for constituent elements identical to those shown in FIG. 1, like reference characters as those in FIG. 1 are used and redundant explanations thereof will be omitted. FIG. 4 is a plan view of the heater 12, showing a modification of the first embodiment.

As shown in FIG. 4, in the present modification, the entire annular sidewall 110 is the moving part 1102 capable of moving upward with respect to the mount face 121. That is, in the present modification, the moving part 1102 is provided all around the mount face 121. The inside diameter of the moving part 1102 is larger than the diameter of the semiconductor substrate 2.

In the present modification, for example, the moving part 1102 incorporates therein a heating wire, thereby having a function of a heater.

According to the present modification, the moving part 1102 is provided all around the mount face 121. Therefore, in whichever radial direction D2 the semiconductor substrate 2 is deviated, the semiconductor substrate 2 can be brought into contact with the inclined face 1101 of the moving part 1102 in the direction of the deviation. Accordingly, the present modification enables positional deviation to be more reliably eliminated.

### Second Embodiment

An embodiment of a semiconductor manufacturing apparatus having a movable heater is explained next as a second embodiment. In the explanations of the second embodiment, as for constituent elements identical to those described in the first embodiment, like reference characters as those in the first embodiment are used and redundant explanations thereof will be omitted.

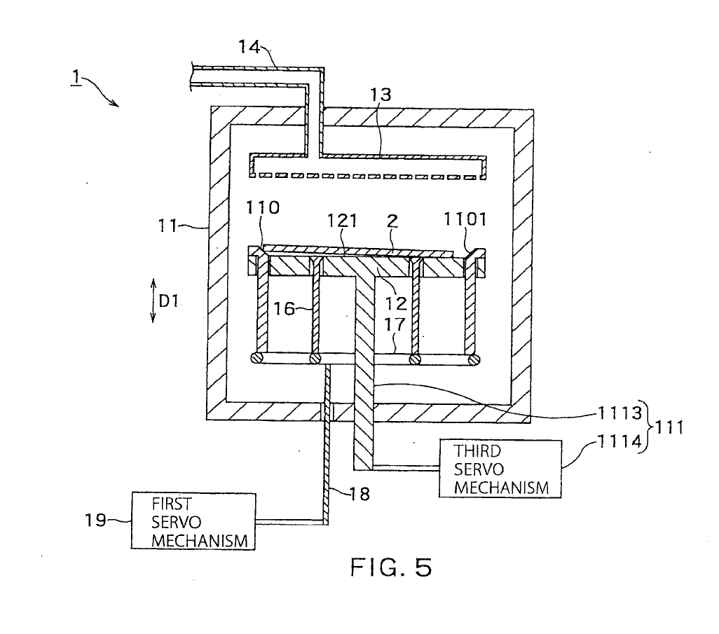

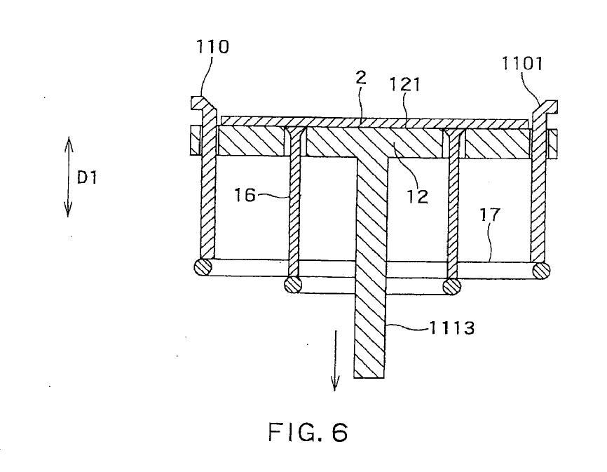

FIG. 5 shows the semiconductor manufacturing apparatus 1 according to the second embodiment. FIG. 6 shows the semiconductor substrate 2 from which positional deviation has been eliminated in the semiconductor manufacturing apparatus 1 shown in FIG. 5. In FIG. 6, an arrow indicates a moving direction of the heater 12. While the sidewall 110 is operated in the first embodiment, the heater 12 is moved in the second embodiment. Also when the heater 12 is moved in this way, the sidewall 110 can be caused to protrude relatively from the mount face 121 and thus the position of the semiconductor substrate 2 can be modified. Therefore, it suffices that the moving mechanism 111 relatively moves the sidewall 110 and the heater 12.

In the second embodiment, the heater 12 is movable in the vertical direction D1. Furthermore, in the second embodiment, the moving mechanism 111 moves the heater 12. Specifically, the moving mechanism 111 includes a support column 1113 and a third servo mechanism 1114. A portion of the support column 1113 on the side of a lower end passes through the chamber 11 to be drawn outside. The lower end of the support column 1113 is connected to the third servo mechanism 1114 outside the chamber 11.

The third servo mechanism 1114 transmits power in the vertical direction D1 to the support column 1113. The third servo mechanism 1114 can include, for example, a motor, a gear that converts a rotational motion of the motor to a translational motion in the vertical direction D1 and that transmits the translational motion to the support column 1113, and a controller for the motor. In the second embodiment, the sidewall 110 has an annular shape that surrounds the entire periphery of the mount face 121 and passes through the heater 12 to extend downward similarly to the modification (FIG. 4) of the first embodiment. The sidewall 110 can also function as the moving part 1102 similarly in the first embodiment or can be fixed in an immovable state.

With the moving mechanism 111 according to the second embodiment, the heater 12, that is, the mount face 121 can be lowered as shown in FIG. 6. By lowering the heater 12, a balance of force (frictional force or moment) that is immobilizing the semiconductor substrate 2 can be lost similarly to the first embodiment. Accordingly, similarly to the first embodiment, the semiconductor substrate 2 can easily slide toward the mount face 121 under its own weight. The lift pins 16 can be lowered together with the heater 12 to prevent the lift pins 16 from interfering with slide of the semiconductor substrate 2.

Therefore, according to the second embodiment, the heater 12 can be lowered and thus positional deviation of the semiconductor substrate 2 can be reliably eliminated as in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a heater capable of heating a semiconductor substrate;
a sidewall located at an outer edge of the heater and protruding upward from a mount face of the heater on which the semiconductor substrate is mounted; and
a moving mechanism relatively moving at least a part of the sidewall and the heater in a substantially perpendicular direction with respect to the mount face.

2. The apparatus of claim 1, wherein a top face of the sidewall is inclined downward as approaching the heater.

3. The apparatus of claim 1, wherein the sidewall has an annular shape surrounding an entire periphery of the mount face.

4. The apparatus of claim 2, wherein the sidewall has an annular shape surrounding an entire periphery of the mount face.

5. The apparatus of claim 2, wherein
a part of the sidewall is a moving part movable in a substantially perpendicular direction with respect to the mount face, and
the moving mechanism moves the moving part.

6. The apparatus of claim 4, wherein
a part of the sidewall is a claw part movable in the substantially perpendicular direction, and
the moving mechanism moves the claw part.

7. The apparatus of claim 5, wherein
the sidewall includes a plurality of the moving parts, and
the moving parts are located along an outer edge of the mount face at substantially equal intervals.

8. The apparatus of claim 6, wherein
the sidewall includes a plurality of the claw parts, and
the claw parts are located along an outer edge of the mount face at substantially equal intervals.

9. The apparatus of claim 1, wherein
entirety of the sidewall is movable in the substantially perpendicular direction, and
the moving mechanism moves the entirety of the sidewall.

10. The apparatus of claim 2, wherein
entirety of the sidewall is movable in the substantially perpendicular direction, and
the moving mechanism moves the entirety of the sidewall.

11. The apparatus of claim 3, wherein
entirety of the sidewall is movable in the substantially perpendicular direction, and
the moving mechanism moves the entirety of the sidewall.

12. The apparatus of claim 4, wherein
entirety of the sidewall is movable in the substantially perpendicular direction, and
the moving mechanism moves the entirety of the sidewall.

13. The apparatus of claim 1, wherein
the heater is movable in the substantially perpendicular direction, and
the moving mechanism moves the heater.

14. The apparatus of claim 2, wherein
the heater is movable in the substantially perpendicular direction, and
the moving mechanism moves the heater.

15. The apparatus of claim 3, wherein
the heater is movable in the substantially perpendicular direction, and
the moving mechanism moves the heater.

16. The apparatus of claim 4, wherein
the heater is movable in the substantially perpendicular direction, and
the moving mechanism moves the heater.

17. The apparatus of claim 1, wherein the apparatus is a CVD (Chemical Vapor Deposition) apparatus in which a non-doped silicate glass film on the semiconductor substrate.
